(19) United States
(12) Patent Application Publication
(10) Pub. No.: US 2026/0240040 A1
(43) Pub. Date: Aug. 13, 2026

(54) ELECTRONIC DEVICE

(71) Applicant: Advanced Semiconductor Engineering, Inc., Kaohsiung (TW)

(72) Inventors: Kuofeng HUANG, Kaohsiung (TW); Cheng-Hsiang HSU, Kaohsiung (TW); Che-Ting LI, Kaohsiung (TW); Chi Hao CHIANG, Kaohsiung (TW); Hsin-Chin CHANG, Kaohsiung (TW)

(73) Assignee: Advanced Semiconductor Engineering, Inc., Kaohsiung (TW)

(21) Appl. No.: 19/050,105

(22) Filed: Feb. 10, 2025

(51) Int. Cl. H01L 25/18; H01L 23/00; H01L 23/367; H01L 23/498; H02M 1/00; H02M 1/08

(52) U.S. Cl. CPC H10W 90/00; H02M 1/0067; H02M 1/08; H10W 40/22; H10W 70/65; H10W 70/657; H10W 90/701; H10W 90/724

(57) ABSTRACT

The present disclosure provides an electronic device. The electronic device includes an operating module, a first converter, a first circuit structure, and a second converter. The first circuit structure supports the first converter. The second converter electrically connects the first converter and the operating module. The first converter is configured to receive an external power not passing through the first circuit structure.

### BACKGROUND

### 1. Technical Field

The present disclosure relates to an electronic device.

### 2. Description of the Related Art

Power management integrated circuits (PMICs) leverage System-in-Package (SiP) technology, including double side molding, 2.5D/3D IC, etc., to integrate multiple chips or components into a package. However, to provide different types of power control and to adapt to demands of high-speed data communication, bulky passive components may be needed. As a result, the package size may be increased, and thus the layout design flexibility may be diminished.

### SUMMARY

In some arrangements, an electronic device includes an operating module, a first converter, a first circuit structure, and a second converter. The first circuit structure supports the first converter. The second converter electrically connects the first converter and the operating module. The first converter is configured to receive an external power not passing through the first circuit structure.

In some arrangements, an electronic device includes a first converter and a second converter. The first converter is configured to receive an external power transmitted along a first transmission path. The second converter at least vertically overlaps the first converter and configured to receive a regulated power from the first converter transmitted along a second transmission path which is free from laterally overlapping the first transmission path.

In some arrangements, an electronic device includes a first converter, a second converter, and a first carrier. The first converter is configured to receive an external power. The second converter is configured to receive a first regulated power from the first converter. The first carrier separates the first converter from the second converter. The carrier defines an opening for accommodating the second converter.

### BRIEF DESCRIPTION OF THE DRAWINGS

Aspects of some arrangements of the present disclosure are best understood from the following detailed description when read with the accompanying figures. It is noted that various structures may not be drawn to scale, and dimensions of the various structures may be arbitrarily increased or reduced for clarity of discussion.

FIG. 1A illustrates a partial layout of an electronic device, in accordance with some arrangements of the present disclosure.

FIG. 1B illustrates a cross-sectional view along line A-A′ of the electronic device as shown in FIG. 1A, in accordance with some arrangements of the present disclosure.

FIG. 1C illustrates a cross-sectional view along line B-B′ of the electronic device as shown in FIG. 1A, in accordance with some arrangements of the present disclosure.

FIG. 1D illustrates a partial enlarged view of the region R of the electronic device as shown in FIG. 1C, in accordance with some arrangements of the present disclosure.

FIG. 1E illustrates a partial layout of FIG. 1D, in accordance with some arrangements of the present disclosure.

FIG. 2 illustrates a cross-sectional view of a first stage power module, in accordance with some arrangements of the present disclosure.

FIG. 3 illustrates a cross-sectional view of an electronic device, in accordance with some arrangements of the present disclosure.

FIG. 4 illustrates a cross-sectional view of an electronic device, in accordance with some arrangements of the present disclosure.

FIG. 5A illustrates a cross-sectional view of an electronic device, in accordance with some arrangements of the present disclosure.

FIG. 5B illustrates a perspective view of an interposer, in accordance with some arrangements of the present disclosure.

FIG. 6 illustrates a cross-sectional view of an electronic device, in accordance with some arrangements of the present disclosure.

FIG. 7 illustrates a top view of an electronic device, in accordance with some arrangements of the present disclosure.

FIG. 8 illustrates a cross-sectional view along line C-C′ of the electronic device as shown in FIG. 7, in accordance with some arrangements of the present disclosure.

### DETAILED DESCRIPTION

The following disclosure provides for many different arrangements, or examples, for implementing different features of the provided subject matter. Specific examples of components and arrangements are described as follows to explain certain aspects of the present disclosure. These are, of course, merely examples and are not intended to be limiting. For example, the formation of a first feature over or on a second feature in the description that follows may include arrangements in which the first and second features are formed or disposed in direct contact, and may also include arrangements in which additional features may be formed or disposed between the first and second features, such that the first and second features may not be in direct contact. In addition, the present disclosure may repeat reference numerals and/or letters in the various examples. This repetition is for the purpose of simplicity and clarity and does not in itself dictate a relationship between the various arrangements and/or configurations discussed.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of arrangements of this disclosure are not deviated from by such arrangement.

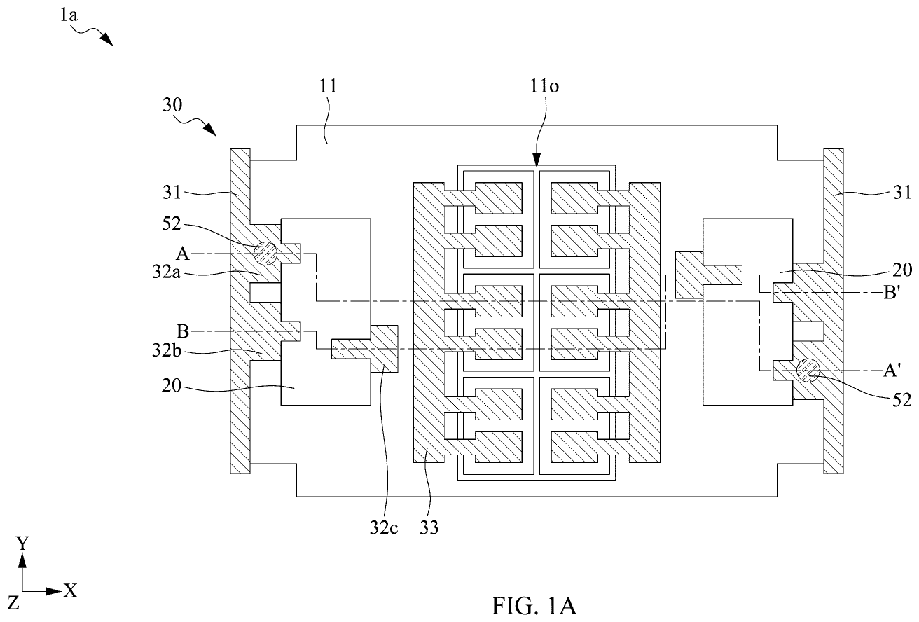

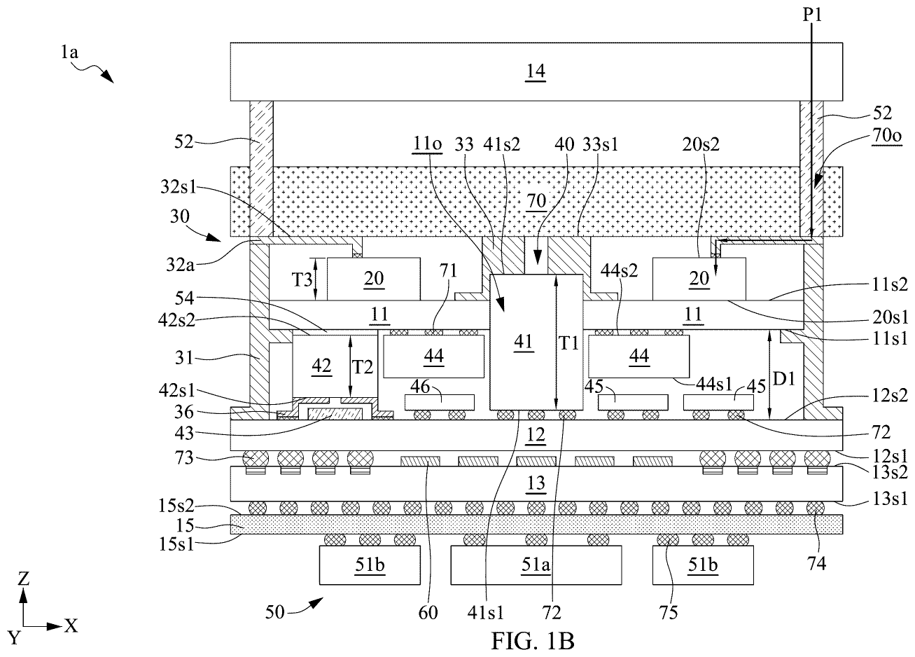

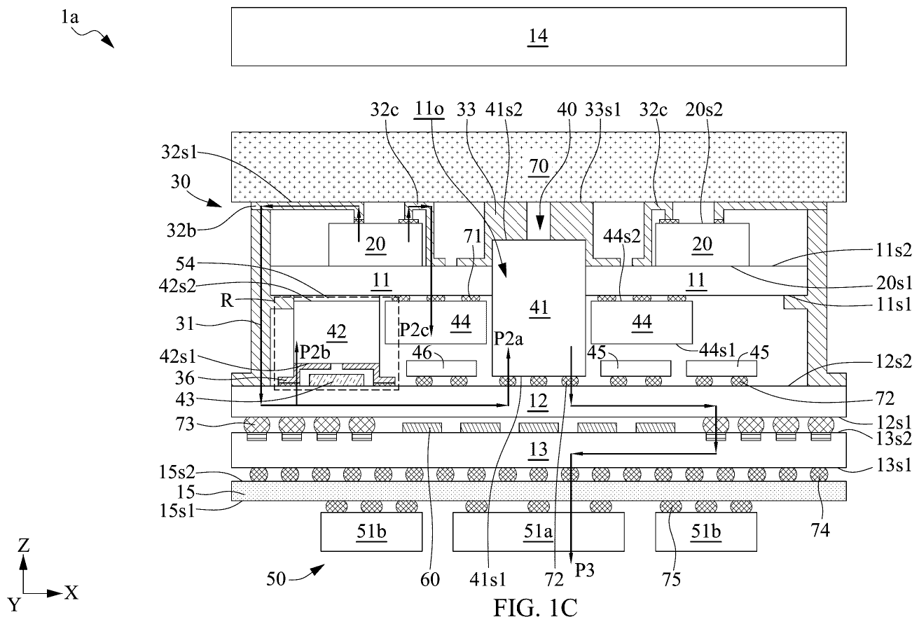

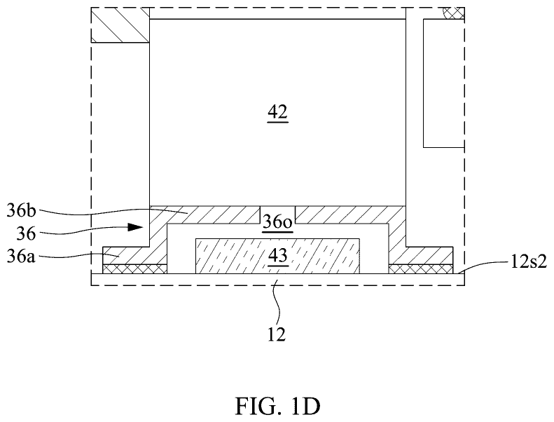

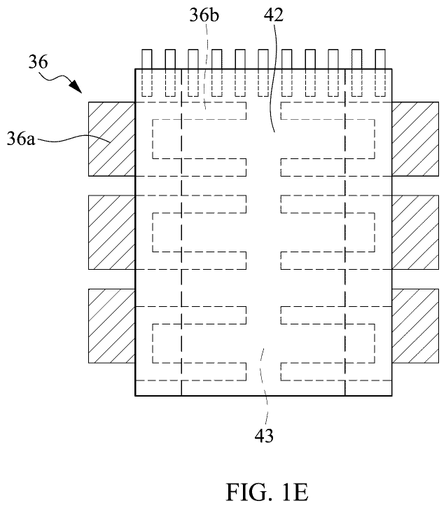

FIGS. 1A to 1E illustrate an electronic device 1a, in accordance with some arrangements of the present disclosure. It should be noted that some features are omitted from the top view, as shown in FIG. 1A, for the sake of brevity.

Please refer to FIGS. 1A, 1B, and 1C; the electronic device 1a may include circuit structures (or carriers) 11, 12, and 13. Each of the circuit structures 11, 12, and 13 may be formed as a printed circuit board (PCB), flexible printed circuit board (FPCB), or other suitable circuit structures. Each of the circuit structures 11, 12, and 13 may include multiple metal layers separated from one another by layers of dielectric material and interconnected by electrically conductive vias. In some embodiments, each of the circuit structures 11, 12, and 13 may be formed of an epoxy resin, a fiberglass-reinforced epoxy resin, an epoxy resin with inorganic fillers, a ceramic material, or a polymer material such as polyimide. The circuit structure 11 may have a surface 11s1 (or lower surface) and a surface 11s2 (or upper surface) opposite to the surface 11s1. The circuit structure 12 may have a surface 12s1 (or lower surface) and a surface 12s2 (or upper surface) opposite to the surface 12s1. The surface 12s2 of the circuit structure 12 may face the surface 11s1 of the circuit structure 11. The circuit structure 13 may have a surface 13s1 (or lower surface) and a surface 13s2 (or upper surface) opposite to the surface 13s1. The surface 13s2 of the circuit structure 13 may face surface 12s1 of the circuit structure 12. Each of the circuit structures 11, 12, and 13 may include a solder resist (not shown) on the upper surface and/or lower surface to fully expose or to expose at least a portion of the conductive pads for electrical connections. The circuit structures 11, 12, and 13 are located at different levels. The circuit structure 12 may be disposed over the circuit structure 13. The circuit structure 11 may be disposed over the circuit structure 12.

In some arrangements, the electronic device 1a may include a first stage power module 20, a conductive structure 30, a second stage power module 40, an operating module 50, passive components 60, and a heat dissipating structure 70.

In some arrangements, the first stage power module 20 (or first power conversion stage or converter or electrical converter) may be disposed on or over the surface 11s2 of the circuit structure 11. In some arrangements, the first stage power module 20 may be configured to convert a higher voltage (e.g., 48 V) to a lower voltage (e.g., 12 V). In some arrangements, the first stage power module 20 may include at least one power module (or converter), which includes a transistor(s), a diode(s), a capacitor(s), an inductor(s), and/or other suitable elements.

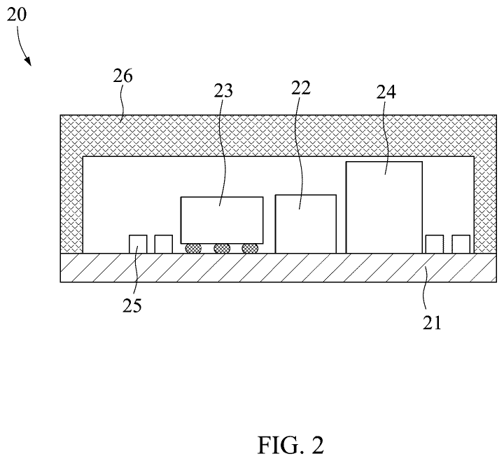

FIG. 2 illustrates a cross-sectional view of the first stage power module 20, in accordance with some arrangements of the present disclosure. In some arrangements, the first stage power module 20 may include a circuit structure 21, an active component 22, a controller 23, passive component 24 and 25, and a housing 26. It should be noted that the first stage power module 20 can include more elements and/or components based on the requirements.

The circuit structure 21 may be formed as a PCB, FPCB, or other suitable circuit structures. The circuit structure 21 may include multiple metal layers separated from one another by layers of dielectric material and interconnected by electrically conductive vias. In some embodiments, the circuit structure 21 may be formed of an epoxy resin, a fiberglass-reinforced epoxy resin, an epoxy resin with inorganic fillers, a ceramic material, or a polymer material such as polyimide. In some arrangements, the first stage power module 20 may include electrical connectors (e.g., solder materials) electrically connecting the circuit structures 11 and 21.

The active component 22, controller 23, and passive components 24 and 25 may be disposed on and electrically connected to the circuit structure 21. In some arrangements, the active component 22 may be a transistor, which includes a gate terminal, a drain terminal, and a source terminal. In some arrangements, the controller 23 may be a switch, which is configured to turn on or turn off the active component 22. In some arrangements, the passive component 24 may be configured to regulate the power of the first stage power module 20. The passive component 24 may include an inductor or other suitable elements. In some arrangements, the passive component 25 may be configured to regulate the power of the first stage power module 20. The passive component 25 may include a capacitor (e.g., a deep trench capacitor (DTC), a multi-layer ceramic capacitor (MLCC) or other capacitors), or other suitable elements.

The housing 26 may be disposed on or over the circuit structure 21. The housing 26 may cover the active component 22, controller 23, and passive components 24 and 25. In some arrangements, the housing 26 may be configured to transmit the heat from the first stage power module 20 to the surroundings. In some arrangements, the housing 26 may include aluminum (Al), copper (Cu), chromium (Cr), tin (Sn), gold (Au), silver (Ag), nickel (Ni) or stainless steel, or a mixture, an alloy, or other combinations thereof.

Please refer back to FIGS. 1A, 1B, and 1C; the first stage power module 20 may have a surface 20s1 (or a lower surface) and a surface 20s2 (or upper surface) opposite to the surface 20s1. In some arrangements, the surface 20s2 may function as an active surface. In this disclosure, the active surface may refer to a surface on which an active circuit or an active circuit region is disposed, or refer to a surface through which a signal (e.g., power signal or data signal) passes.

In some arrangements, the electronic device 1a may include a power delivery board 14 (or external device). The power delivery board 14 may be disposed on or over the first stage power module 20. In some arrangements, the power delivery board 14 may be configured to provide the first stage power module 20 with a relatively great power (e.g., 48 V). In some arrangements, the power delivery board 14 may include a PCB, FPCB, or other suitable circuit structures. One or more electronic components (not shown) may be disposed on or over the power delivery board 14. For example, the electronic device 1a may include a power management integrated circuit (PMIC) die on or within the power delivery board 14.

In some arrangements, the conductive structure 30 may be disposed on or over the surface 12s2 of the circuit structure 12. In some arrangements, the conductive structure 30 may support the surface 11s1 of the circuit structure 11. In some arrangements, the conductive structure 30 may include an insulative portion (e.g., insulated mask) and a conductive pattern on or embedded within the insulative portion. In some arrangements, the conductive pattern may include a metallic material, such as copper (Cu), aluminum (Al), chromium (Cr), tin (Sn), gold (Au), silver (Ag), nickel (Ni) or stainless steel, or a mixture, an alloy, or other combinations thereof. In some arrangements, the dimension (e.g., line width) of the conductive pattern of the conductive structure 30 may be greater than that of the metal layer of the circuit structures 11, 12, and 13. Therefore, the resistance of the conductive pattern of the conductive structure 30 may be less than that of the metal layer of the circuit structures 11, 12, and 13.

The conductive structure 30 may include a conductive lead. The conductive structure 30 may include a main portion 31 and fingers 32a, 32b, and 32c. The main portion 31 may be a frame supported by the surface 12s2 of the circuit structure 12. In some arrangements, the main portion 31 may surround the circuit structure 11. In some arrangements, the main portion 31 may surround the first stage power module 20. In some arrangements, the main portion 31 may surround the second stage power module 40. The main portion 31 may include a plate portion (not annotated) supporting the circuit structure 11 and in contact with the surface 11s1 of the circuit structure 11.

The fingers 32a, 32b, and 32c may disposed on or over the main portion 31 and extend from the main portion 31. The fingers 32a, 32b, and 32c may be electrically connected to terminals of the first stage power module 20. As shown in FIG. 1B, the finger 32a may be configured to electrically connect the power delivery board 14 and the first stage power module 20.

In some arrangements, the electronic device 1a may further include conductive elements 52. The conductive elements 52 may be configured to electrically connect the power delivery board 14 and the first stage power module 20. In some arrangements, the conductive elements 52 may be disposed on or over the conductive structure 30. The conductive elements 52 may be detachable from the conductive structure 30. The conductive elements 52 may be detachable from the power delivery board 14. In some arrangements, the conductive elements 52 may include a pogo pin, conductive pillar, or other suitable conductive elements.

As shown in FIG. 1B, the surface 20s2 of the first stage power module 20 may be configured to receive a power P1 (or voltage or external power) from the power delivery board 14. In some arrangements, the conductive elements 52 may be configured to provide the electrical path (or power path) conducting the power P1. In some arrangements, the finger 32a of the conductive structure 30 may be configured to provide the electrical path (or power path) conducting the power P1. In this arrangement, the electrical path of the power P1 does not enter the circuit structure 11. In this arrangement, the electrical path of the power P1 does not pass through the circuit structure 11. Since the conductive structure 30 has a relatively low resistance compared to the circuit structure 11, this arrangement may help reduce the power loss of power P1.

In some arrangements, the second stage power module 40 (or second power conversion stage or converter or electrical converter) may be disposed on or over the surface 11s2 of the circuit structure 11. In some arrangements, the second stage power module 40 may be configured to convert a higher voltage (e.g., 12 V) to a lower voltage (e.g., 8 V, 6 V, 4 V, 2 V, or less). In some arrangements, the second stage power module 40 may vertically overlap the first stage power module 20 or overlap the first stage power module 20 along the substantial Z direction.

In some arrangements, the second stage power module 40 may include a voltage regulator 41, a voltage regulator 42, a controller 43, a voltage regulator 44, and passive components 45.

In some arrangements, the voltage regulators 41 and 42 (or converters) may be configured to convert a higher voltage (e.g., 12 V) to a lower voltage (e.g., 8 V or 6 V). The voltage regulators 41 and 42 may be electrically connected to the circuit structure 11. The voltage regulators 41 and 42 may include multiple elements on a circuit structure (e.g., PCB). For example, the voltage regulators 41 and 42 may include a transistor(s), a controller(s), and a passive element(s). In some arrangements, the voltage regulators 41 and 42 may be configured to transmit a signal(s) with a relatively high current (e.g., a current greater than 100 A). The voltage regulators 41 and 42 may have different dimensions (e.g., vertical dimensions or thicknesses). For example, the voltage regulator 41 may have a thickness T1. The voltage regulator 42 may have a thickness T2 that is less than the thickness T1. In some arrangements, the thickness T1 may be greater than or equal to 7 mm, such as 7 mm, 8 mm, 9 mm, 10 mm, or more. In some arrangements, the thickness T2 may range between 3 mm and 7 mm, such as 3 mm, 4 mm, 5 mm, 6 mm, or 7 mm. The first stage power module 20 may have a thickness T3. In some arrangements, the thickness T3 may be less than the thickness T1. In some arrangements, the thickness T3 may range between about 3 mm and 7 mm, such as 3 mm, 4 mm, 5 mm, 6 mm, or 7 mm.

In some arrangements, the voltage regulator 41 may be disposed on or over the surface 12s2 of the circuit structure 12. In some arrangements, the voltage regulator 41 may penetrate the circuit structure 11. In some arrangements, the circuit structure 11 may define an opening 11o for accommodating the voltage regulator 41. In some arrangements, the voltage regulator 41 may be free from vertically overlapping the circuit structure 11 or free from overlapping the circuit structure 11 along the substantial Z direction. In some arrangements, the voltage regulator 41 may laterally overlap the circuit structure 11 or overlap the circuit structure 11 along the substantial X direction. In some arrangements, the voltage regulator 41 may laterally overlap the first stage power module 20 or overlap the first stage power module 20 along the substantial X direction. The voltage regulator 41 may have a surface 41s1 (or lower surface) and a surface 41s2 (or upper surface) opposite to the surface 41s1. In some arrangements, the surface 41s1 of the voltage regulator 41 may function as an active surface. In some arrangements, the surface 41s2 of the voltage regulator 41 may be at a level (or elevation) higher than the surface 11s2 of the circuit structure 11 with respect to the surface 11s1 of the circuit structure 11.

In some arrangements, the electronic device 1a may include a spacer 33 (or a thermal transmission structure or a conductive spacer). In some arrangements, the spacer 33 may be configured to transmit a heat from the voltage regulator 41 toward the heat dissipating structure 70. In some arrangements, the spacer 33 may be configured to transmit a heat from the circuit structure 11 toward the heat dissipating structure 70. In some arrangements, the spacer 33 may include a metallic material, such as copper (Cu), aluminum (Al), chromium (Cr), tin (Sn), gold (Au), silver (Ag), nickel (Ni) or stainless steel, or a mixture, an alloy, or other combinations thereof. In some arrangements, the spacer 33 may be disposed on or over the surface 41s2 of the voltage regulator 41. The spacer 33 may be disposed between the voltage regulator 41 and the heat dissipating structure 70. In some arrangements, the spacer 33 may cover a portion of the lateral surface of the voltage regulator 41 which extends between the surface 41s1 and surface 41s2. The spacer 33 may be disposed on or over the surface 11s2 of the circuit structure 11. In some arrangements, the spacer 33 may be configured to support the heat dissipating structure 70. For example, the spacer 33 may be in direct contact with the heat dissipating structure 70 or may contact the heat dissipating structure 70 through a thermal transmission adhesive. In some arrangements, a surface 32s1 (or upper surface) of the fingers 32 may be at a level substantially the same as a surface 33s1 (or upper surface) of the spacer 33.

The voltage regulator 41 is designed to deliver a relatively high power output compared to other voltage regulators, such as voltage regulator 44, which may result in significant heat generation. To address this, the circuit structure 11 includes a thermal transmission channel (e.g., opening 11o) that facilitates heat dissipation from the voltage regulator 41. Additionally, some components of the second stage power module 40, including the voltage regulator 41, may be positioned within the opening 11o. This arrangement can reduce the distance D1 between circuit structures 11 and 12, thereby decreasing the overall vertical dimension of the electronic device 1a.

The voltage regulator 42 may be disposed on or over the surface 12s2 of the circuit structure 12. In some arrangements, the voltage regulator 42 may be disposed between the circuit structures 11 and 12. The voltage regulator 42 may have a surface 42s1 (or lower surface) and a surface 42s2 (or upper surface) opposite to the surface 42s1. In some arrangements, the surface 42s1 of the voltage regulator 42 may be an active surface. In some arrangements, the electronic device 1a may include an adhesive 54 between the surface 42s2 and the circuit structure 11. The adhesive 54 may be configured to transmit a heat from the voltage regulator 42 toward the circuit structure 11. In some arrangements, the adhesive 54 may include a thermal interface material (TIM) or other suitable materials.

Please refer to FIGS. 1D and 1E; the electronic device 1a may include a conductive structure 36 (or spacer or conductive spacer). In some arrangements, the conductive structure 36 may be configured to electrically connect the voltage regulator 42 and the circuit structure 12. In some arrangements, the conductive structure 36 may be configured to support the voltage regulator 42. In some arrangements, the conductive structure 36 may be disposed on or over the surface 12s2 of the circuit structure 12. In some arrangements, the conductive structure 36 may define a space 36o for accommodating the controller 43. In some arrangements, the conductive structure 36 may include an insulative portion (e.g., insulated mask) and a conductive pattern on or embedded within the insulative portion. In some arrangements, the conductive pattern may include a metallic material, such as copper (Cu), aluminum (Al), chromium (Cr), tin (Sn), gold (Au), silver (Ag), nickel (Ni) or stainless steel, or a mixture, an alloy, or other combinations thereof. The conductive structure 36 may include a conductive lead. The conductive structure 36 may include a base 36a connected to the circuit structure 12 and fingers 36b for supporting the voltage regulator 42.

In some arrangements, the controller 43 may be disposed on or over the surface 12s2 of the circuit structure 12. In some arrangements, the controller 43 may be electrically connected to the voltage regulator 42 by the conductive structure 36. In some arrangements, the controller 43 may be configured to turn on or turn off the voltage regulator 42. In some arrangements, the voltage regulator 42 may vertically overlap the controller 43.

Please refer back to FIGS. 1A, 1B, and 1C; the voltage regulator 44 may be disposed on or under the surface 11s1 of the circuit structure 11. The voltage regulator 44 may be attached to the surface 11s1 of the circuit structure 11. The voltage regulator 44 may have a surface 44s1 (or a lower surface) and a surface 44s2 (or upper surface) opposite to the surface 44s1. In some arrangements, the surface 44s2 may function as an active surface.

In some arrangements, the voltage regulator 44 may be configured to convert a higher voltage (e.g., 12 V) to a lower voltage (e.g., 4 V, 3.3 V, 2 V or less). The voltage regulator 44 may be electrically connected to the circuit structure 11 through electrical connectors 71. In some arrangements, the electrical connectors 71 may include a reflowable material. The electrical connectors 71 may be or include electrical contacts, such as solder balls (e.g., controlled collapse chip connection (C4) bumps, a ball grid array (BGA), a land grid array (LGA)), conductive bumps, or the like. The electrical connectors 71 may include alloys of gold and tin solder or alloys of silver and tin solder, or other suitable materials. In other arrangements, the voltage regulator 44 may be electrically connected to the circuit structure 11 by hybrid-bond techniques, which involve a bonding between metallic materials (e.g., a bonding between copper and copper) and a bonding between dielectric materials (e.g., a bonding between oxide and oxide). In other arrangements, the voltage regulator 44 may be electrically connected to the circuit structure 11 by a conductive wire.

The passive components 45 may be disposed on or over the surface 12s2 of the circuit structure 12. In some arrangements, the passive components 45 may be configured to regulate the power from the voltage regulator 41, voltage regulator 42, and/or voltage regulator 44. In some arrangements, the passive components 45 may include inductors, capacitors, resistors, or other suitable passive elements. In some arrangements, the passive components 45 may be disposed between the circuit structures 11 and 12. In some arrangements, the passive components 45 may vertically overlap the voltage regulator 44. The passive components 45 may be electrically connected to the circuit structure 12 by electrical connectors 72. In some arrangements, the electrical connectors 72 may include a reflowable material. The electrical connectors 72 may be or include electrical contacts, such as solder balls (e.g., controlled collapse chip connection (C4) bumps, a ball grid array (BGA), a land grid array (LGA)), conductive bumps, or the like. The electrical connectors 72 may include alloys of gold and tin solder or alloys of silver and tin solder, or other suitable materials. In other arrangements, the passive components 45 may be electrically connected to the circuit structure 12 by hybrid-bond techniques, which involve a bonding between metallic materials (e.g., a bonding between copper and copper) and a bonding between dielectric materials (e.g., a bonding between oxide and oxide).

In other arrangements, the second stage power module 40 may further include a voltage regulator 46 attached to the surface 12s2 of the circuit structure 12. The voltage regulator 46 may be configured to convert a higher voltage (e.g., 12 V) to a lower voltage (e.g., 4 V, 3.3 V, 2 V or less). The voltage regulator 46 may be configured to provide the input/output die with a power signal. It should be noted that the second stage power module 40 can include more modules or passive components based on the requirements.

In some arrangements, the passive components 60 may be disposed on or over the surface 13s2 of the circuit structure 13. The passive components 60 may be electrically connected to the circuit structure 12. In some arrangements, the passive components 60 may be disposed between the circuit structures 12 and 13. The passive components 60 may be electrically connected to the circuit structure 13. In some arrangements, the passive components 60 may be configured to regulate the power from the second stage power module 40 toward the operating module 50. In some arrangements, the passive components 60 may include capacitors. In some arrangements, the passive components 60 may include an input capacitor (Cin) through which the power flows before being delivered to the second stage power module 40 (e.g., the voltage regulator 41). In some arrangements, the passive components 60 may include an output capacitor through which the power flows after being transmitted from the second stage power module 40 (e.g., the voltage regulator 41).

The electronic device 1a may include electrical connectors 73. The electrical connectors 73 may be disposed between the circuit structures 12 and 13. The electrical connectors 73 may be electrically connected to the circuit structures 12 and 13. In some arrangements, the electrical connectors 73 may include a reflowable material. The electrical connectors 73 may be or include electrical contacts, such as solder balls (e.g., controlled collapse chip connection (C4) bumps, a ball grid array (BGA), a land grid array (LGA)), conductive bumps, or the like. The electrical connectors 73 may include alloys of gold and tin solder or alloys of silver and tin solder, or other suitable materials. In some arrangements, the dimension (e.g., vertical dimension or thickness) of the passive components 60 may be less than that of the electrical connectors 73.

In some arrangements, the electronic device 1a may include a carrier 15. In some arrangements, the carrier 15 may be disposed on or under the surface 13s1 of the circuit structure 13. In some arrangements, the carrier 15 may include a semiconductor substrate, such as silicon, germanium, and other group III-V and group IV materials. The carrier 15 may include metal lines and vias, including but not limited to through-silicon vias (TSVs) for interconnection. In some arrangements, the carrier 15 may include a wafer, a panel form or other suitable forms. The carrier 15 may have a surface 15s1 (or a lower surface) and a surface 15s2 (or an upper surface) opposite to the surface 15s1.

The carrier 15 may be electrically connected to the circuit structure 13 through electrical connectors 74. The carrier 15 may be configured to support the operating module 50. In some arrangements, the electrical connectors 74 may include a reflowable material. The electrical connectors 74 may be or include electrical contacts, such as solder balls (e.g., controlled collapse chip connection (C4) bumps, a ball grid array (BGA), a land grid array (LGA)), conductive bumps, or the like. The electrical connectors 74 may include alloys of gold and tin solder or alloys of silver and tin solder, or other suitable materials.

In some arrangements, the operating module 50 may be disposed on or under the surface 15s1 of the carrier 15. In some arrangements, the operating module 50 may be configured to generate non-power signals, such as analog signals, digital signals, clock signals or other electrical signals other than power signals. The operating module 50 may include electronic components 51a and 51b. In some arrangements, the electronic components 51a and 51b may be disposed on or under the surface 15s1 of the carrier 15. In some arrangements, the electronic component 51a may include a processor or other suitable components. In some arrangements, the electronic component 51a may include an active device, such as a central processing unit (CPU), a microprocessor unit (MPU), a graphics processing unit (GPU), a microcontroller unit (MCU), a radio frequency integrated circuit (RFIC), an application-specific IC (ASIC), a field-programmable gate array (FPGA), or another type of IC. In some arrangements, the electronic components 51b may include a data storage unit or other suitable components. The electronic components 51b may be electrically connected to the electronic component 51a through the carrier 15. The electronic components 51b may be disposed on or under the surface 15s1 of the carrier 15. In some arrangements, the electronic components 51b may be configured to store the signals from the electronic component 51a and/or other devices. In some arrangements, the electronic components 51b may include a high band memory (HBM) die, dynamic random access memory (DRAM) die, static random access memory (SRAM) die, or other suitable memory devices. In some arrangements, the operating module 50 may further include other components, such as input/output dies configured to receive regulated power from the second stage power module 40 and/or transmit a processed signal to other devices (not shown). The electronic components 51a and 51b may be electrically connected to the carrier 15 by electrical connectors 75. In some arrangements, the electrical connectors 75 may include a reflowable material. The electrical connectors 75 may be or include electrical contacts, such as solder balls (e.g., controlled collapse chip connection (C4) bumps, a ball grid array (BGA), a land grid array (LGA)), conductive bumps, or the like. The electrical connectors 75 may include alloys of gold and tin solder or alloys of silver and tin solder, or other suitable materials. In other arrangements, the electronic components 51a and 51b may be electrically connected to the carrier 15 by hybrid-bond techniques, which involve a bonding between metallic materials (e.g., a bonding between copper and copper) and a bonding between dielectric materials (e.g., a bonding between oxide and oxide).

As shown in FIG. 1C, the conductive structure 30 may be configured to transmit powers P2a, P2b and P2c (or regulated powers) by the fingers 32b and 32c. In some arrangements, the voltage regulator 41 may be configured to receive the power P2a from the first stage power module 20 through the conductive structure 30 and the circuit structure 12. In some arrangements, the voltage regulator 42 may be configured to receive the power P2b from the first stage power module 20 through the conductive structure 30, the circuit structure 12, and the conductive structure 36. In some arrangements, the voltage regulator 44 may be configured to receive the power P2c from the first stage power module 20 through the fingers 32c and the circuit structure 11.

The operating module 50 may be configured to receive a power P3 (or regulated power) from the second stage power module 40 (e.g., voltage regulator 41). In some arrangements, the circuit structure 12 may be configured to provide the electrical path (or power path) conducting the power P3. In some arrangements, the circuit structure 13 may be configured to provide the electrical path (or power path) conducting the power P3. In some arrangements, the carrier 15 may be configured to provide the electrical path (or power path) conducting the power P3. In some arrangements, the second stage power module 40 may provide the operating module 50 with powers at different levels (e.g., 8 V, 6 V, 4 V, 2 V, or less).

In some arrangements, the heat dissipating structure 70 may be disposed on or over the first stage power module 20. In some arrangements, the heat dissipating structure 70 may be disposed on or over the conductive structure 30. In some arrangements, the heat dissipating structure 70 may be disposed between the power delivery board 14 and the first stage power module 20. The heat dissipating structure 70 may be configured to transmit heat from the conductive structure 30 and/or the second stage power module 40 to the surrounding environment. In some arrangements, the heat dissipating structure 70 may define openings 70o for accommodating the conductive elements 52. The heat dissipating structure 70 may include a cold plate, which may include a vapor chamber, heat pipe, and/or other suitable elements.

In this arrangement, multiple modules (e.g., voltage regulators and passive components) of the second stage power module 40 with different dimensions are disposed between the circuit structures 11 and 12. Further, the circuit structure 11 defines the opening 11o for accommodating some modules of the second stage power module 40. This arrangement helps to reduce the vertical dimension of the electronic device 1a. Moreover, the opening 11o may facilitate the connection between the spacer 33 and the voltage regulator 41, thereby improving the heat dissipation of the electronic device 1a.

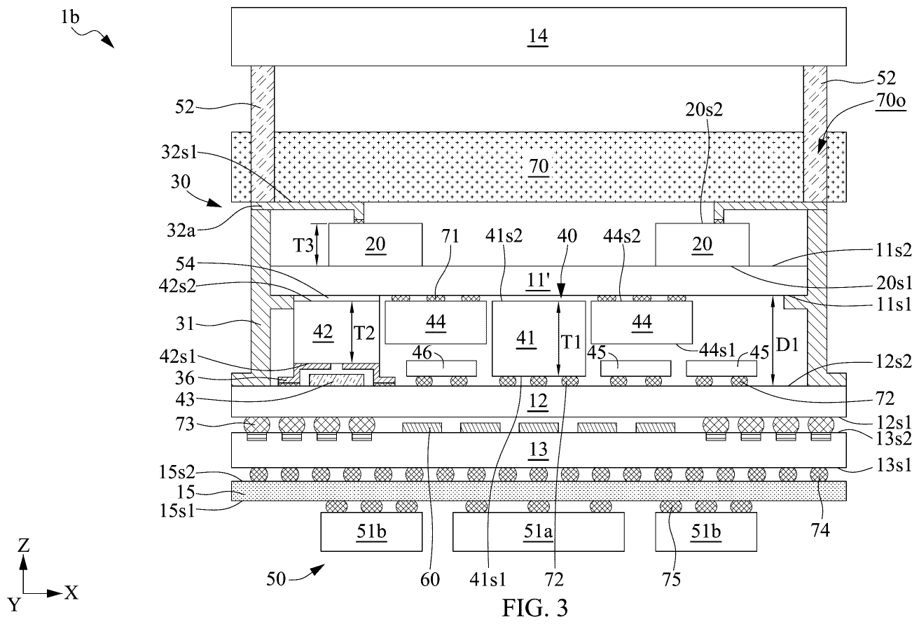

FIG. 3 is a cross-section of an electronic device 1b in accordance with some arrangements of the present disclosure. The electronic device 1b is similar to the electronic device 1a in FIG. 1B, differing as follows.

The electronic device 1b may include a circuit structure 11′. In some arrangements, the circuit structure 11′ does not have openings. In some arrangements, the thickness T1 of the voltage regulator 41 may be substantially equal to or less than the distance D1 between the circuit structures 11′ and 12. The voltage regulator 41 may be disposed between the circuit structures 11′ and 12. In this arrangement, the processes for forming the openings of the circuit structure 11′ can be omitted, hereby simplifying the manufacturing steps for the electronic device 1b.

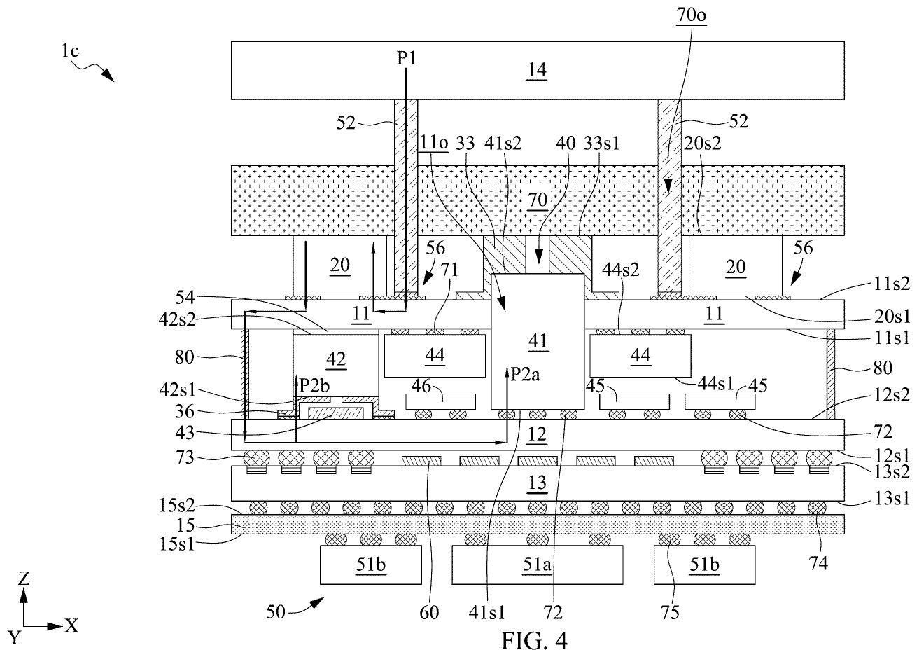

FIG. 4 is a cross-section of an electronic device 1c in accordance with some arrangements of the present disclosure. The electronic device 1c is similar to the electronic device 1a in FIG. 1B, differing as follows.

In some arrangements, the surface 20s1 of the first stage power module 20 may function as an active surface. In some arrangements, the electronic device 1c may include a conductive pattern 56 on or within the surface 11s2 of the circuit structure 11. The conductive pattern 56 may include a connector electrically connecting the conductive elements 52 and the first stage power module 20.

In some arrangements, the conductive pattern 56c and the conductive elements 52 may collectively provide the first stage power module 20 with an electrical path conducting the power P1.

In some arrangements, the electronic device 1c may include conductive elements 80. The conductive elements 80 may be configured to electrically connect the circuit structures 12 and 13. In some arrangements, the conductive elements 80 may include a conductive pillar or other suitable conductive elements. In some arrangements, each of the conductive elements 80 may be a conductive lead which includes multiple fingers extending between the circuit structures 12 and 13. In some arrangements, the circuit structure 12, the circuit structure 13, and the conductive elements 80 may be configured to provide the second stage power module 40 with electrical paths conducting the powers P2a and P2b.

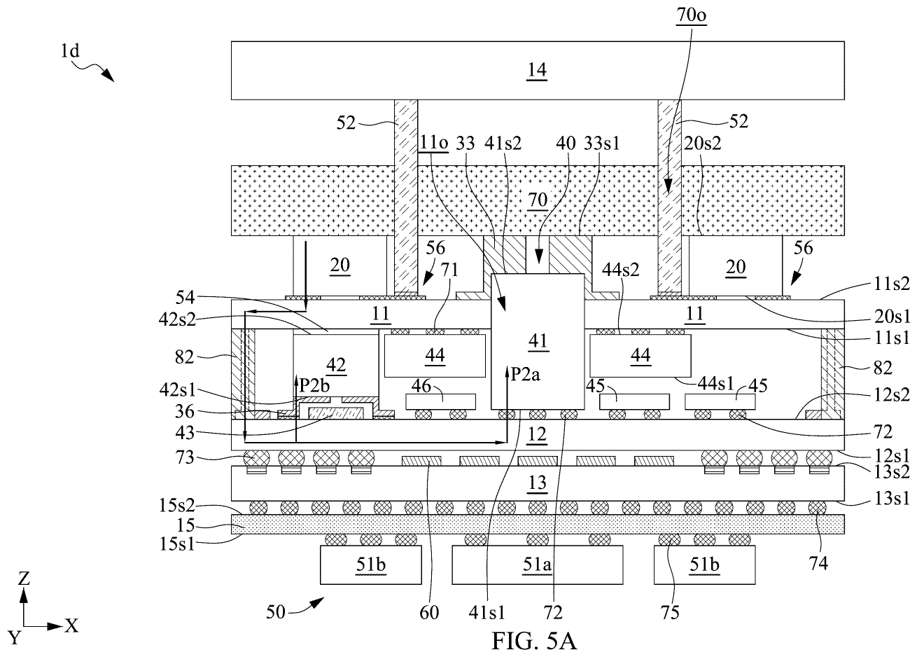

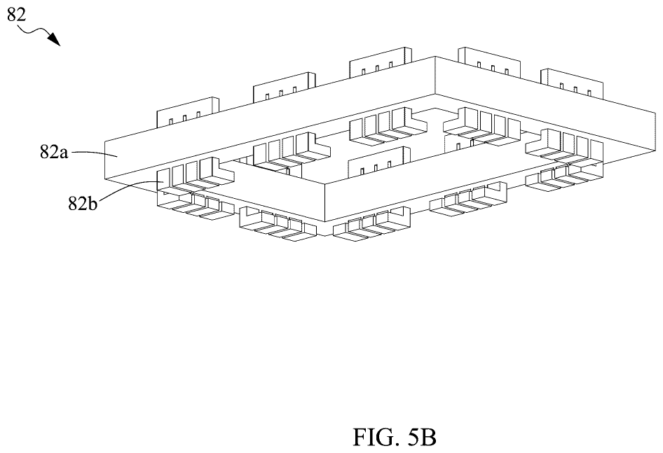

FIG. 5A is a cross-section of an electronic device 1d in accordance with some arrangements of the present disclosure. The electronic device 1d is similar to the electronic device 1a in FIG. 1B, differing as follows.

In some arrangements, the electronic device 1d may include an interposer 82. The interposer 82 may be configured to electrically connect the circuit structures 12 and 13. In some arrangements, the interposer 82 may be a ring interposer which defines a space for accommodating the second stage power module 40. In some arrangements, the interposer 82 may be configured to provide the second stage power module 40 with electrical paths conducting the powers P2a and P2b.

As shown in FIG. 5B, the interposer 82 may include a frame 82a and conductive elements 82b encapsulated by the frame 82a. The frame 82a may include an insulative material, such as resin or other suitable materials. The conductive elements 82b may include a metallic material, such as copper (Cu), aluminum (Al), chromium (Cr), tin (Sn), gold (Au), silver (Ag), nickel (Ni) or stainless steel, or a mixture, an alloy, or other combinations thereof. In some arrangements, the interposer 82 may surround the second stage power module 40. The use of interposer 82 may eliminate the need for surface mount technology (SMT), potentially improving the manufacturing cycle time for the electronic device 1d.

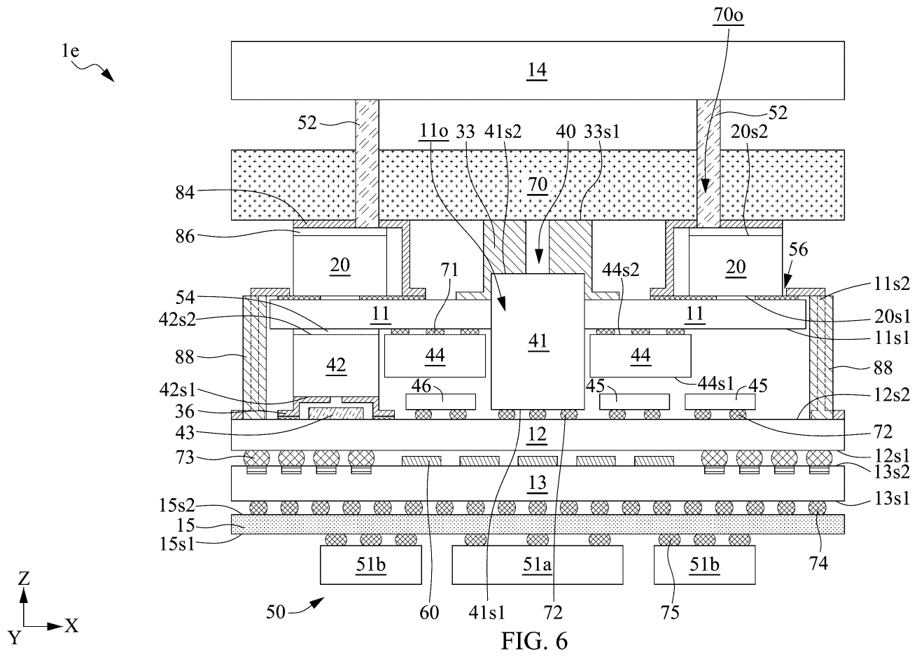

FIG. 6 is a cross-section of an electronic device 1e in accordance with some arrangements of the present disclosure. The electronic device 1e is similar to the electronic device 1a in FIG. 1B, differing as follows.

In some arrangements, the electronic device 1e may include conductive structures 84. In some arrangements, the conductive structures 84 may be configured to electrically connect the first stage power module 20 and the conductive pattern 56. In some arrangements, the conductive structures 84 may be configured to transmit the heat from the first stage power module 20 toward the heat dissipating structure 70. In some arrangements, the conductive structures 84 may include a metallic clip including a first end connected to the surface 20s2 of the first stage power module 20 and a second end connected to the conductive pattern 56 over the surface 11s2 of the circuit structure 11.

In some arrangements, the electronic device 1e may include thermally conducting material 86. The thermally conducting material 86 may be disposed between the surface 20s2 of the first stage power module 20 and the conductive structure 84. In some arrangements, the thermally conducting material 86 may be configured to transmit the heat from the first stage power module 20 toward the conductive structure 84. The thermally conducting material 86 may include a thermal interface material (TIM) or other suitable materials.

In some arrangements, the electronic device 1e may include a conductive structure 88. In some arrangements, the conductive structure 88 may be configured to electrically connect the circuit structures 11 and 12. In some arrangements, the conductive structure 88 may include a ring interposer, a conductive lead, or other suitable components.

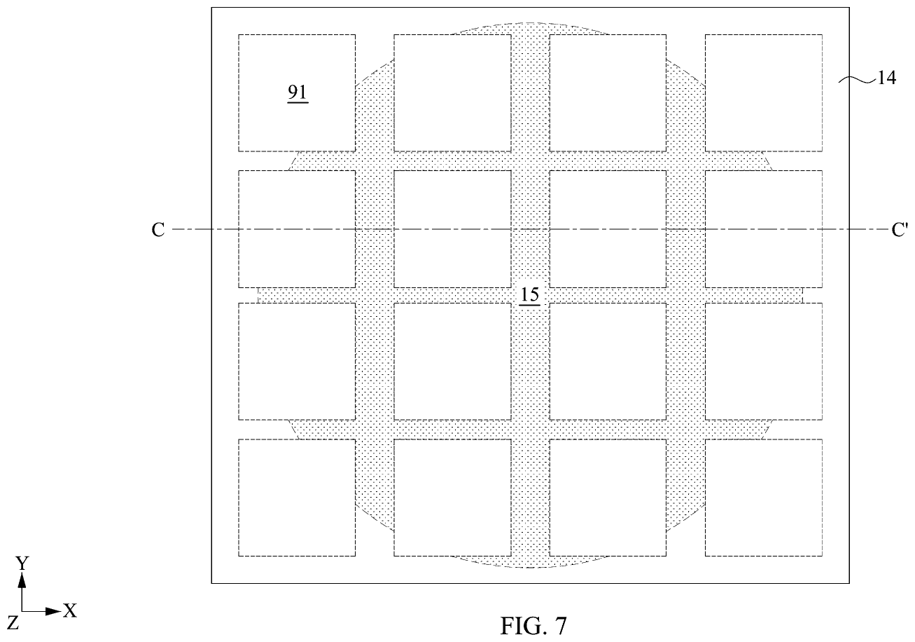

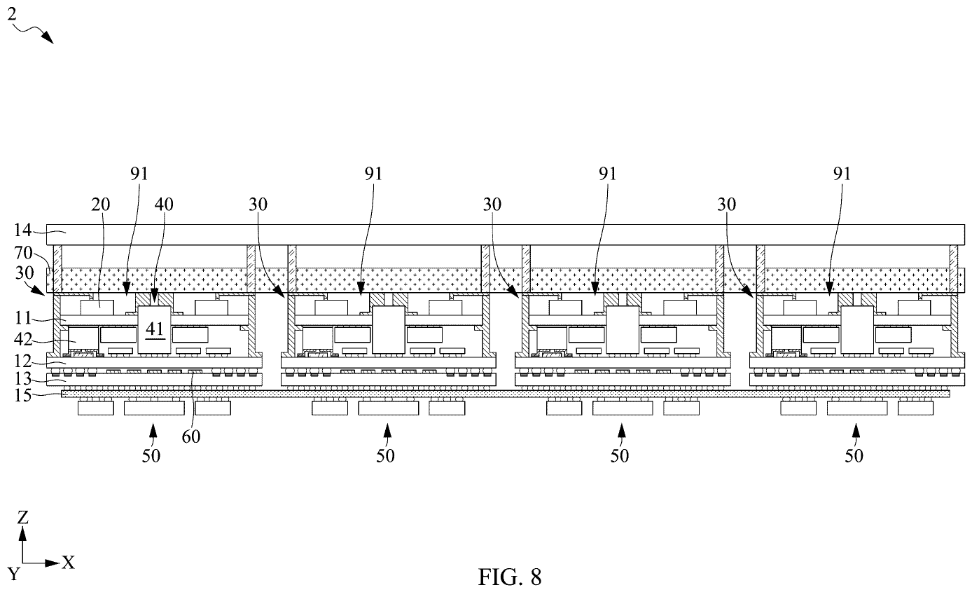

FIGS. 7 and 8 illustrate an electronic device 2, in accordance with some arrangements of the present disclosure. In some arrangements, the electronic device 2 may include multiple packages 91 over the carrier 15. The packages 91 may include a structure the same as or similar to that of one of the electronic devices 1a to 1e. More specifically, the packages 91 may include the structure including the circuit structure 13 and the elements disposed over the circuit structure 13. For example, each of the packages 91 may include the first stage power module 20, the second stage power module, and other interconnections for electrical connection. In some arrangements, each of the packages 91 may function as a voltage regulated module configured to provide the operating module 50 with regulated powers. As shown in FIG. 7, the carrier 15 may have a circular profile. The carrier 15 may have a dimension greater than that of the circuit structure 11. The circuit structure 11 may overhang the carrier 15. For example, a portion of the circuit structure 11 may be free from vertically overlapping the carrier 15. The circuit structure 12 may overhang the carrier 15. For example, a portion of the circuit structure 12 may be free from vertically overlapping the carrier 15. The circuit structure 13 may overhang the carrier 15. For example, a portion of the circuit structure 13 may be free from vertically overlapping the carrier 15.

In some arrangements, each of the packages 91 may be configured to supply regulated powers to the operating module 50 independently. By this arrangement, the dimension (e.g., surface area extending along the XY plane) of the electronic device 2 may be reduced.

In some arrangements, an electronic device includes an operating module, a first converter, a first circuit structure, and a second converter. The first circuit structure supports the first converter. The second converter electrically connects the first converter and the operating module. The first converter is configured to receive an external power not passing through the first circuit structure.

In some arrangements, the first converter is configured to regulate the external power and to provide the second converter with a regulated power.

In some arrangements, the electronic device includes a conductive lead configured to transmit the regulated power without passing through the first circuit structure.

In some arrangements, the electronic device includes a heat dissipating structure over the first converter, wherein the first converter is configured to provide an electrical transmission path of the external power passing through the heat dissipating structure.

In some arrangements, the electronic device includes a conductive lead configured to transmit a regulated power from the first converter to the second converter.

In some arrangements, the conductive lead is further configured to transmit the external power to the first converter.

In some arrangements, the conductive lead surrounds the first circuit structure.

In some arrangements, the electronic device includes a second circuit structure under the first circuit structure, wherein the second converter comprises a plurality of modules between the first circuit structure and the second circuit structure, and two of the plurality of modules overlap each other along a direction from the first circuit structure to the second circuit structure.

In some arrangements, the electronic device includes a conductive spacer supporting the second converter and configured to transmit a regulated power from the first converter to the second converter.

In some arrangements, the first circuit structure defines a thermal transmission channel for heat dissipation from the second converter.

In some arrangements, the electronic device includes a heat dissipating structure thermally coupled to the second converter through the thermal transmission channel.

In some arrangements, the electronic device includes a conductive lead thermally coupling the heat dissipating structure and the second converter.

In some arrangements, an electronic device includes a first converter and a second converter. The first converter is configured to receive an external power transmitted along a first transmission path. The second converter at least vertically overlaps the first converter and configured to receive a regulated power from the first converter transmitted along a second transmission path which is free from laterally overlapping the first transmission path.

In some arrangements, the electronic device includes a first carrier supporting the first converter, wherein the first carrier defines an opening accommodating the second converter

In some arrangements, the electronic device includes a second carrier supporting the second converter, wherein the second carrier is configured to transmit the regulated power.

In some arrangements, the electronic device includes a conductive lead comprising a first portion configured to transmit the external power and a second portion configured to transmit the regulated power.

In some arrangements, wherein a vertical dimension of the second converter is greater than a distance between the first carrier and the second carrier

In some arrangements, the electronic device includes a heat dissipating structure disposed over the first converter and a spacer disposed between the second converter and the heat dissipating structure.

In some arrangements, the electronic device includes a first carrier separating the first converter from the second converter and a conductive lead electrically connecting the first converter and the second converter, wherein an upper surface of the conductive lead is at a level substantially the same as a level of an upper surface of the spacer with respect to the first carrier.

In some arrangements, the heat dissipating structure defines an opening for accommodating a conductive element configured to transmit the external power.

In some arrangements, the spacer laterally overlaps the first converter.

In some arrangements, the conductive lead supports the first carrier.

In some arrangements, an active surface of the first converter faces away from the second converter.

In some arrangements, an active surface of the second converter faces away from the first converter.

In some arrangements, an electronic device includes a first converter, a second converter, and a first carrier. The first converter is configured to receive an external power. The second converter is configured to receive a first regulated power from the first converter. The first carrier separates the first converter from the second converter. The carrier defines an opening for accommodating the second converter.

In some arrangements, the electronic device includes a conductive lead surrounding the first carrier and configured to transmit the external power and the first regulated power.

In some arrangements, the electronic device includes a power delivery board configured to transmit the external power to the first converter and a heat dissipating structure between the first converter and the power delivery board.

In some arrangements, the conductive lead thermally couples the heat dissipating structure and the first converter.

In some arrangements, the electronic device includes a second carrier supporting the conductive lead, wherein the second converter comprises a first component attached to the first carrier and a second component attached to the second carrier.

In some arrangements, the electronic device includes an operating module configured to receive a second regulated power from the second converter, wherein the second carrier is configured to transmit the first regulated power and the second regulated power.

As used herein, the singular terms “a,” “an,” and “the” may include a plurality of referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 10⁴ S/m, such as at least 10⁵ S/m or at least 10⁶ S/m. The electrical conductivity of a material can sometimes vary with temperature. Unless otherwise specified, the electrical conductivity of a material is measured at room temperature.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation of less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, two numerical values can be deemed to be “substantially” the same or equal if a difference between the values is less than or equal to ±10% of an average of the values, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, “substantially” parallel can refer to a range of angular variation relative to 0° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°. For example, “substantially” perpendicular can refer to a range of angular variation relative to 90° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific arrangements thereof, these descriptions and illustrations do not limit the present disclosure. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other arrangements of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. An electronic device, comprising:
an operating module;
a first converter;
a first circuit structure supporting the first converter; and
a second converter electrically connecting the first converter and the operating module,
wherein the first converter is configured to receive an external power without passing through the first circuit structure.

2. The electronic device of claim 1, wherein the first converter is configured to regulate the external power and to provide the second converter with a regulated power.

3. The electronic device of claim 2, further comprising:
a conductive lead configured to transmit the regulated power without passing through the first circuit structure.

4. The electronic device of claim 1, further comprising:
a heat dissipating structure over the first converter, wherein the first converter is configured to provide an electrical transmission path of the external power passing through the heat dissipating structure.

5. The electronic device of claim 1, further comprising:
a conductive lead configured to transmit a regulated power from the first converter to the second converter.

6. The electronic device of claim 5, wherein the conductive lead is further configured to transmit the external power to the first converter.

7. The electronic device of claim 1, further comprising:
a second circuit structure under the first circuit structure, wherein the second converter comprises a plurality of modules between the first circuit structure and the second circuit structure, and two of the plurality of modules overlap each other along a direction from the first circuit structure to the second circuit structure.

8. The electronic device of claim 1, further comprising:
a conductive spacer supporting the second converter and configured to transmit a regulated power from the first converter to the second converter.

9. The electronic device of claim 1, wherein the first circuit structure defines a thermal transmission channel for heat dissipation from the second converter.

10. An electronic device, comprising:
a first converter configured to receive an external power transmitted along a first transmission path; and
a second converter laterally overlapping the first converter and configured to receive a regulated power from the first converter transmitted along a second transmission path that is at least partially laterally overlapping the first transmission path.

11. The electronic device of claim 10, further comprising:
a first carrier supporting the first converter, wherein the first carrier defines an opening accommodating the second converter.

12. The electronic device of claim 11, further comprising:
a second carrier supporting the second converter, wherein the second carrier is configured to transmit the regulated power.

13. The electronic device of claim 12, wherein a vertical dimension of the second converter is greater than a distance between the first carrier and the second carrier.

14. The electronic device of claim 10, further comprising:
a heat dissipating structure disposed over the first converter; and
a spacer disposed between the second converter and the heat dissipating structure.

15. The electronic device of claim 14, further comprising:
a first carrier separating the first converter from the second converter; and
a conductive lead electrically connecting the first converter and the second converter, wherein an upper surface of the conductive lead is at a level substantially the same as a level of an upper surface of the spacer with respect to the first carrier.

16. The electronic device of claim 14, wherein the heat dissipating structure defines an opening for accommodating a conductive element configured to transmit the external power.

17. The electronic device of claim 12, further comprising a conductive lead supporting the first carrier.

18. An electronic device, comprising:
a first converter configured to receive an external power;
a second converter configured to receive a first regulated power from the first converter; and
a first carrier separating the first converter from the second converter,
wherein the first carrier defines an opening for accommodating the second converter.

19. The electronic device of claim 18, further comprising:
a conductive lead surrounding the first carrier and configured to transmit the external power and the first regulated power;
a second carrier supporting the conductive lead, wherein the second converter comprises a first component attached to the first carrier and a second component attached to the second carrier.

20. The electronic device of claim 19, further comprising:
an operating module configured to receive a second regulated power from the second converter,
wherein the second carrier is configured to transmit the first regulated power and the second regulated power.
